(19) United States
(12) Patent Application Publication
(10) Pub. No.: US 2007/0173023 A1
(43) Pub. Date: Jul. 26, 2007

(54) Semiconductor device manufacturing method

(76) Inventors: Gen Okazaki, Hyogo (JP); Naoki Kotani, Hyogo (JP); Tokuhiko Tamaki, Osaka (JP); Akio Sebe, Osaka (JP)

Correspondence Address: MCDERMOTT WILL & EMERY LLP, 600 13TH STREET, N.W., WASHINGTON, DC, 20005-3096, US

(21) Appl. No.: 11/540,756

(22) Filed: Oct. 2, 2006

(30) Foreign Application Priority Data
Jan. 24, 2006 (JP) 2006-015004

(51) Int. Cl. H01L 21/336; H01L 21/385

(52) U.S. Cl. 438/289; 438/558

(57) ABSTRACT

After gate insulating film formation films are formed in an element formation region of a semiconductor substrate, a gate electrode formation film is formed on the gate insulating film formation films. A fluorine-containing insulting film is formed on the gate electrode formation film. Then, thermal treatment is performed to diffuse and introduce the fluorine contained in the fluorine-containing insulating film to interfaces between the semiconductor substrate and the gate insulting film formation films.

### CROSS REFERENCE TO RELATED APPLICATIONS

This Non-provisional application claims priority under 35 U.S.C. § 119(a) on Patent Application No. 2006-015004 filed in Japan on Jan. 24, 2006, the entire contents of which are hereby incorporated by reference.

### BACKGROUND OF THE INVENTION

1. Field of the Invention

The present invention relates to a semiconductor manufacturing method.

2. Background Art

In recent years, miniaturization of elements for semiconductor devices (for example, MISFETs and the like) is being progressed, and high integration, high-speed operation, and low power consumption are contemplated in the semiconductor devices. In association with miniaturization of the elements for the semiconductor devices, gate insulating films are thinned further and further, and electric fields applied to the gate insulating films increase more and more. Under the circumstances, it is essential to prevent NBTI (Negative Bias Temperature Instability) degradation caused due to the presence of dangling bonds at an interface between a semiconductor substrate and a gate insulating film in semiconductor devices (especially in p-type MISFETs). The dangling bonds include, for example, Si dangling bonds generated in such a way that terminals of silicon atoms located at the outermost surface of a silicon substrate remain unbonded.

In order to prevent NBTI degradation caused due to the presence of the dangling bonds, there was proposed a conventional semiconductor device manufacturing method, for example, in which a reaction of dangling bonds (Si dangling bonds) present at the interface between the semiconductor substrate and the gate insulating film with hydrogen (H) is caused by hydrogen annealing to form Si—H bonds terminated with hydrogen, thereby consuming the dangling bonds. As a result, NBTI degradation caused due to the presence of the dangling bonds is prevented.

In general, however, Si—H bond energy is comparatively low. Therefore, in conventional semiconductor devices, which use MIS transistors (hereinafter referred to merely as “transistors”), hydrogen will be eliminated chronologically to generate the dangling bonds again at the interface between the semiconductor substrate and the gate insulting film, which means a chronological increase in dangling bonds. This lowers threshold voltage of the transistors chronologically, inviting a chronological decrease in drain saturation current, namely, causing NBTI degradation. In view of this, complete prevention of NBTI degradation caused due to the presence of dangling bonds cannot be attained in the conventional semiconductor devices.

Under the circumstances, another conventional semiconductor device manufacturing method was proposed in which a reaction of fluorine (F) rather than hydrogen (H) with dangling bonds (Si dangling bonds) is caused to generate Si—F bonds terminated with fluorine (see, for example, Japanese Patent Application Laid Open Publication No. 02-159069A). In general, Si—F bond energy is larger than Si—H bond energy, inviting no chronological elimination of fluorine even with the use of the transistor.

The latter conventional semiconductor device manufacturing method, however, involves following problems.

In latter the prior art semiconductor device manufacturing method, when annealing is performed after implantation of fluorine to a polysilicon film to be a gate electrode, that is, a gate electrode formation film, outward diffusion occurs in which part of fluorine implanted in the polysilicon film is released outside of the polysilicon film.

Therefore, not all of the fluorine implanted in the polysilicon film can be used as a diffusion source in the annealing, namely, only fluorine not diffused outward and remaining in the polysilicon film is used as the diffusion source and is diffused at the interface between the semiconductor substrate and the gate insulating film. This inhibits reliable diffusion of fluorine to the interface between the semiconductor substrate and the gate insulating film, and a sufficient amount of fluorine cannot be introduced to the interface therebetween. As a result, the amount of fluorine diffused and introduced to the interface between the semiconductor substrate and the gate insulating film does not reach the amount of the dangling bonds (Si dangling bonds), resulting in the dangling bonds remaining at the interface therebetween.

Hence, NBTI degradation is caused due to the presence of dangling bonds (in other words, fixed charges) remaining at the interface between the semiconductor substrate and the gate insulating film, disabling provision of a semiconductor device having highly reliable transistors.

### SUMMARY OF THE INVENTION

The present invention has been made in view of the foregoing and has its object of providing a semiconductor device manufacturing method in which NBTI degradation caused due to dangling bonds present at the interface between a semiconductor substrate and a gate insulating film is prevented by preventing outward diffusion of fluorine implanted to the interface between the semiconductor substrate and the gate insulating film in thermal treatment.

In order to solve the above problems, a semiconductor device manufacturing method according to one aspect of the present invention includes the steps of: (a) forming a gate insulating film formation film in an element formation region on a semiconductor substrate; (b) forming a gate electrode formation film on the gate insulating film formation film; (c) forming a fluorine-containing insulting film on the gate electrode formation film; and (d) diffusing and introducing, by thermal treatment, fluorine contained in the fluorine-containing insulating film to an interface between the semiconductor substrate and the gate insulting film formation film.

In the semiconductor manufacturing method according to the aspect of the present invention, the fluorine-containing insulating film (for example, a FSG film or the like) that covers the surface of the gate electrode formation film is preconditioned to contain a sufficient amount of fluorine, and fluorine is less diffused outwardly from the surface of the fluorine-containing insulating film than from the surface of a conventional fluorine-containing polysilicon film. Accordingly, the fluorine-containing insulating film not only functions as a diffusion source of fluorine but also functions as a cap layer, suppressing outward diffusion of fluorine.

Suppression of outward diffusion of fluorine in the thermal treatment ensures diffusion and introduction of fluorine contained in the fluorine-containing insulating film to the interface between the semiconductor substrate and the gate insulating film formation film, thereby preventing dangling bonds from remaining at the interface therebetween.

In the semiconductor device manufacturing method according to the aspect of the present invention, it is preferable to further include the step of: (x) implanting fluorine to the gate electrode formation film after the step (b) and before the step (c), wherein the step (d) includes a step of diffusing and introducing the fluorine implanted in the gate electrode formation film to the interface between the semiconductor substrate and the gate insulating film formation film.

In the above arrangement, the fluorine-containing insulating film (for example, a FSG film or the like) that covers the surface of the gate electrode formation film to which fluorine is implanted is preconditioned to contain a sufficient amount of fluorine, and hence, there is no path through which fluorine implanted in the gate electrode formation film enters into the fluorine-containing insulating film in the thermal treatment. Thus, the fluorine-containing insulating film functions as a cap layer, with a result that outward diffusion of fluorine is prevented surely.

In the case where a mere insulating film (for example, a SiO₂ film or the like) is used as a cap layer rather than the fluorine-containing insulating film, in the thermal treatment, fluorine enters into the insulating film of SiO₂ film or the like containing no fluorine, and the entering fluorine passes through the insulating film and is diffused outwardly. As a result, the insulating film functions as a cap layer insufficiently. In contrast, with the use of the fluorine-containing insulating film as a cap layer as in the present invention, there is no path through which fluorine enters in the thermal treatment in the fluorine-containing insulating film which contains a sufficient amount of fluorine, sufficiently functioning as a cap layer.

Accordingly, fluorine can be diffused and introduced reliably to the interface between the semiconductor substrate and the gate insulating film formation film in the thermal treatment with no outward diffusion of the fluorine contained in the fluorine-containing insulating film caused and even with no outward diffusion of the fluorine implanted in the gate electrode formation film. Hence, a concentration of fluorine introduced in the interface between the semiconductor substrate and the gate insulating film formation film can be increased.

In turn, a sufficient amount of fluorine (that is, an amount of fluorine corresponding to the amount of dangling bonds) can be diffused and introduced reliably to the interface between the semiconductor substrate and the gate insulating film formation film, surely preventing the dangling bonds from remaining at the interface therebetween.

In the semiconductor device manufacturing method according the aspect of the present invention, it is preferable to further include the steps of: (e) removing the fluorine-containing insulating film after the step (d); (f) forming a gate insulting film and a gate electrode by patterning the gate insulating film formation film and the gate electrode formation film; and (g) forming an extension region in a region of the semiconductor substrate which is located below each side of the gate electrode after the step (f).

With the above arrangement, as described above, the dangling bonds can be prevented from remaining at the interface between the semiconductor substrate and the gate insulating film formation film. As a result, a transistor with no dangling bonds remaining at the interface therebetween can be attained.

Accordingly, NBTI degradation caused due to the presence of dangling bonds at the interface between the semiconductor substrate and the gate insulating film can be prevented, with a result that a method for manufacturing a semiconductor device having highly reliable transistors can be provided.

In the semiconductor device manufacturing method according to the aspect of the present invention, it is preferable to further includes the step of: (h) forming a sidewall on each side of the gate electrode after the step (g); and (i) forming a source/drain region in a region of the semiconductor substrate which is located below each side of the sidewall after the step (h).

In the semiconductor device manufacturing method according to the aspect of the present invention, it is preferable that the step (a) includes a step of forming a first gate insulating film formation film as a part of the gate insulating film formation film in a first region in the element formation region and forming a second gate insulating film formation film as the other part of the gate insulting film formation film in a second region other than the first region in the element formation region and that the step (b) includes a step of forming a first gate electrode formation film as a part of the gate electrode formation film on the first gate insulating formation film and forming a second gate electrode formation film as the other part of the gate electrode formation film on the second gate insulating film formation film.

With the above arrangement, outward diffusion of fluorine can be suppressed in the thermal treatment. As a result, fluorine can be diffused and introduced reliably to the interface between the semiconductor substrate and the first gate insulating film formation film and to the interface between the semiconductor substrate and the second gate insulating film formation film with no outward diffusion of the fluorine contained in the fluorine-containing insulating film caused. Hence, the dangling bonds can be prevented from remaining at the interface between the semiconductor substrate and the first gate insulating film formation film and at the interface between the semiconductor substrate and the second insulating film formation film.

In the semiconductor device manufacturing method according to the aspect of the present invention, it is preferable to further include the step of: (x) implanting fluorine to one of the first gate electrode formation film and the second gate electrode formation film after the step (b) and before the step (c), wherein the step (d) includes a step of diffusing and introducing the fluorine implanted in the step (x) to an interface between the semiconductor substrate and the first gate insulating film formation film or the second gate insulating film formation film which is located below the one of the gate electrode formation films.

With the above arrangement, when fluorine is selectively implanted to, for example, the first gate electrode formation film (or the second gate electrode formation film) in the step of implanting fluorine to the gate electrode formation film, not only the fluorine selectively implanted to the first gate electrode formation film (or the second gate electrode formation film) but also the fluorine contained in the fluorine-containing insulating film are diffused and introduced to the interface between the semiconductor substrate and the first gate insulating film formation film (or the second gate insulating film formation film), which is to compose a transistor at which NBTI degradation might be caused especially significantly, and only the fluorine contained in the fluorine-containing insulting film is diffused and introduced to the interface between the semiconductor substrate and the second gate insulating film formation film (or the first gate insulating film formation film), which is to compose a transistor other than the transistor at which NBTI degradation might be caused especially significantly.

Thus, selective implantation of fluorine to one of the gate electrode formation films according to a degree of NBTI degradation to be caused in each transistor leads to selective diffusion and introduction of the fluorine implanted in the first gate electrode formation film (or the second gate electrode formation film) to only the interface between the semiconductor substrate and the first gate insulating film formation film (or the second gate insulating film formation film) which is to compose the transistor at which NBTI degradation might be caused especially significantly, in the thermal treatment, effectively preventing NBIT degradation.

Further, only the fluorine contained in the fluorine-containing insulating film can be diffused and introduced to the interface between the semiconductor substrate and the second gate insulating film formation film (or the first gate insulating film formation film) which is to compose a transistor other than the transistor at which NBTI degradation might be caused especially significantly. As a result, surplus fluorine, that is, fluorine in excess of the dangling bonds can be effectively prevented from being introduced.

In the semiconductor device manufacturing method according to the aspect of the present invention, it is preferable to further include the steps of: (e) removing the fluorine-containing insulating film after the step (d); (f) forming a first gate insulating film and a first gate electrode by patterning the first gate insulating film formation film and the first gate electrode formation film and a second gate insulating film and a second gate electrode by patterning the second gate insulating film formation film and the second gate electrode formation film; and (g) forming an extension region in a region of the semiconductor substrate which is located below each side of the first gate electrode and forming a LDD region in a region of the semiconductor substrate which is located below each side of the second gate electrode after the step (f).

The above arrangement attains the first transistor with no dangling bonds remaining at the interface between the semiconductor substrate and the first gate insulating film and the second transistor with no dangling bonds remaining at the interface between the semiconductor substrate and the second gate insulating film, so that NBTI degradation caused due to the presence of dangling bonds at the interface between the semiconductor substrate and the first gate insulating film can be prevented while NBTI degradation caused due to the presence of dangling bonds remaining at the interface between the semiconductor substrate and the second gate insulating film can be prevented. Hence, a semiconductor device having highly reliable transistors can be provided.

In the semiconductor device manufacturing method according to the aspect of the present invention, it is preferable to further include the steps of: (h) forming a first sidewall on each side of the first gate electrode and a second sidewall on each side of the second gate electrode after the step (g); and (i) forming a first source/drain region in a region of the semiconductor substrate which is located below each side of the first sidewall and a second source/drain region in a region of the semiconductor substrate which is located below each side of the second sidewall after the step (h).

As descried above, in the semiconductor device manufacturing method according the aspect of the present invention, the fluorine-containing insulating film (for example, a FSG film or the like) is preconditioned to contain a sufficient amount of fluorine, and fluorine is less diffused outwardly from the surface of the fluorine-containing insulating film than from the surface of a conventional fluorine-containing polysilicon film. Accordingly, the fluorine-containing insulating film functions as a cap layer, suppressing outward diffusion of fluorine.

Accordingly, fluorine can be diffused and introduced reliably to the interfaces between the semiconductor substrate and the gate insulating film formation films with no outward diffusion of the fluorine contained in the fluorine-containing insulating film (and the fluorine implanted in the gate electrode formation film) caused, preventing dangling bonds from remaining at the interfaces between the semiconductor substrate and the gate insulating films.

Hence, a transistor with no dangling bonds remaining at the interfaces between the semiconductor substrate and the gate insulating films can be attained, preventing NBTI degradation caused due to the presence of dangling bonds at the interfaces between the semiconductor substrate and the gate insulating films. As a result, a semiconductor device having highly reliable transistors can be provided.

### BRIEF DESCRIPTION OF THE DRAWINGS

FIG. 1A to FIG. 1D are sections showing main steps of a semiconductor device manufacturing method according to Embodiment 1 of the present invention.

FIG. 2A to FIG. 2C are sections showing main steps of the semiconductor device manufacturing method according to Embodiment 1 of the present invention.

FIG. 3A to FIG. 3C are sections showing main steps of the semiconductor device manufacturing method according to Embodiment 1 of the present invention.

FIG. 4A to FIG. 4D are sections showing main steps of a semiconductor device manufacturing method according to Embodiment 2 of the present invention.

FIG. 5A to FIG. 5C are sections showing main steps of the semiconductor device manufacturing method according to Embodiment 2 of the present invention.

FIG. 6A to FIG. 6C are sections showing main steps of the semiconductor device manufacturing method according to Embodiment 2 of the present invention.

FIG. 7A to FIG. 7D are sections showing main steps of a semiconductor device manufacturing method according to Embodiment 3 of the present invention.

FIG. 8A to FIG. 8C are sections showing main steps of the semiconductor device manufacturing method according to Embodiment 3 of the present invention.

FIG. 9A to FIG. 9C are sections showing main steps of the semiconductor device manufacturing method according to Embodiment 3 of the present invention.

### DESCRIPTION OF THE PREFERRED EMBODIMENTS

Embodiments of the present invention will be described below with reference to the accompanying drawings.

### Embodiment 1

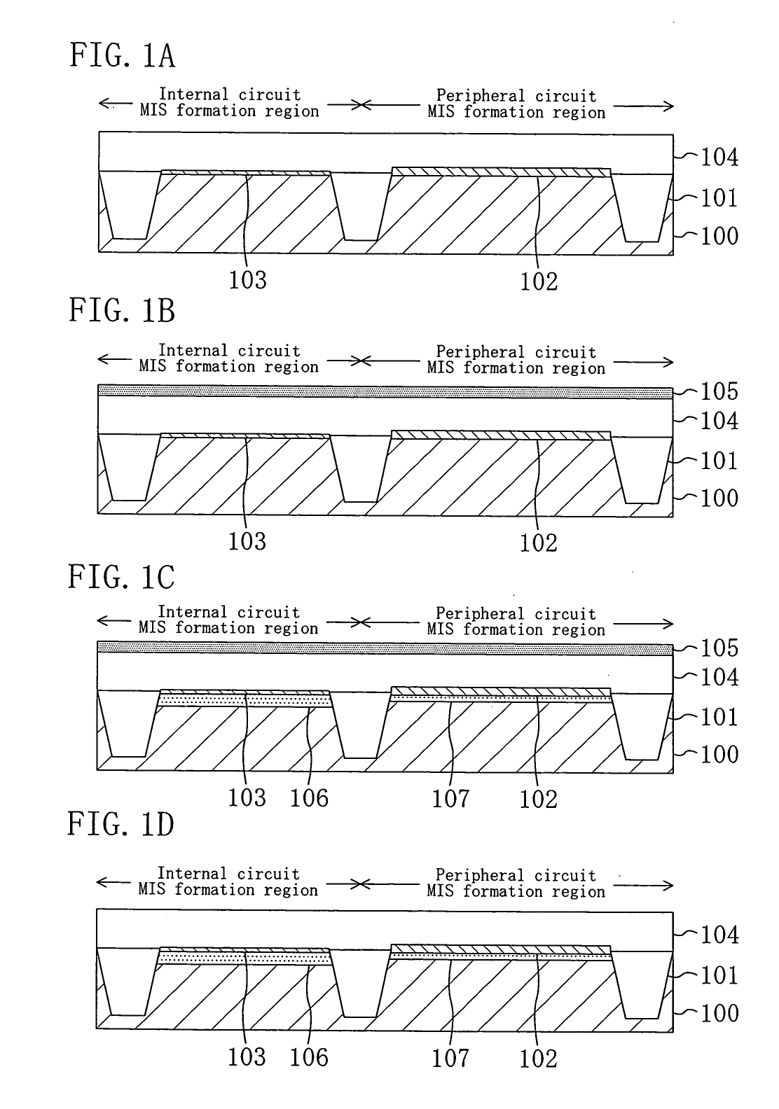

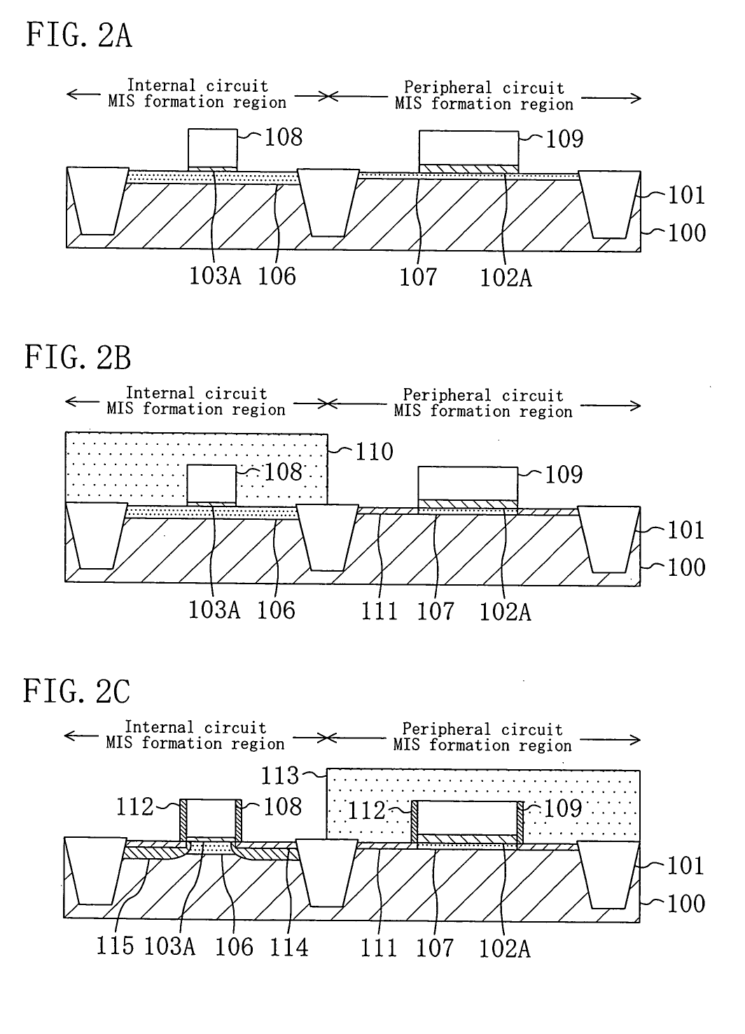

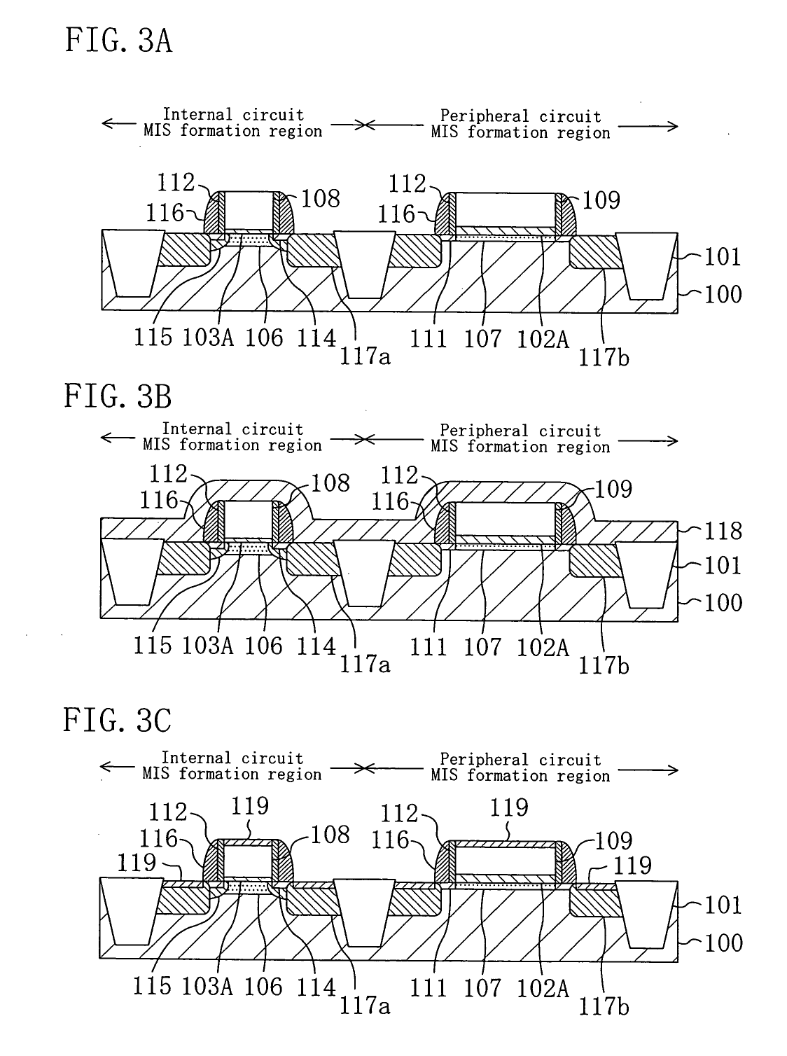

A semiconductor device manufacturing method according to Embodiment 1 of the present invention will be described by referring to a method for manufacturing a p-type MISFET with reference to FIG. 1A to FIG. 1D, FIG. 2A to FIG. 2C, and FIG. 3A to FIG. 3C. FIG. 1A to FIG. 1D, FIG. 2A to FIG. 2C, and FIG. 3A to FIG. 3C are sections showing main steps of the semiconductor device manufacturing method according to Embodiment 1 of the present invention, specifically, a method for manufacturing a semiconductor device including an internal circuit transistor and a peripheral circuit transistor. In each drawing, the left side indicates an internal circuit MIS formation region while the right side indicates a peripheral circuit MIS formation region.

As shown in FIG. 1A, a trench is formed in a semiconductor substrate 100 made of silicon by reactive ion etching, and a P-TEOS film, for example, is filled in the thus formed trench to form an element isolation region 101 having a shallow trench isolation (STI) structure.

Subsequently, after a gate insulting film formation film having a thickness of 5 nm to 8 nm is formed on the surface of the semiconductor substrate 100 by thermal oxidation, a part of the gate insulating film formation film which is formed on the surface of the semiconductor substrate 100 in the internal circuit MIS formation region is removed selectively by photolithography and etching, thereby forming a peripheral circuit gate insulting film formation film 102 having a thickness of 5 nm to 8 nm on the surface of the semiconductor substrate 100 in the peripheral circuit MIS formation region. Then, an internal circuit gate insulating film formation film 103 having a thickness of 2 nm is formed on the surface of the semiconductor substrate 100 in the internal circuit MIS formation region by thermal oxidation.

Next, polycrystalline silicon film 104 is deposited on the semiconductor substrate 100 by chemical vapor deposition (CVD).

Thereafter, as shown in FIG. 1B, a FSG (Fluorinated Silicate Glass) film 105, for example, is deposited as a fluorine-containing insulating film on the polycrystalline silicon film 104 by CVD. The fluorine-containing insulating film of the FSG film 105 or the like means an insulating film preconditioned to contain a sufficient amount of fluorine.

Subsequently, as shown in FIG. 1C, the fluorine contained in the FSG film 105 is diffused and introduced to the interfaces between the semiconductor substrate 100 and the gate insulating film formation films 102, 103 by thermal treatment. Whereby, an internal circuit fluorine introduced region 106 is formed at the interface between the semiconductor substrate 100 and the internal circuit gate insulating film formation film 103 while a peripheral circuit fluorine introduced region 107 is formed at the interface between the semiconductor substrate 100 and the peripheral circuit gate insulating film formation film 102. As to the thermal treatment, conditions are adjusted so that the fluorine contained in the FSG film 105 is diffused to and reaches the interface between the semiconductor substrate 100 and the gate insulating film formation films 102, 103. Wherein, the fluorine from the FSG film 105 is introduced to the polycrystalline silicon film 104 in the thermal treatment, so that the polycrystalline silicon film 104 serves as a fluorine-containing film as well.

As shown in FIG. 1D, only the FSG film 105 is then removed selectively by wet etching.

Next, as shown in FIG. 2A, after a mask (not shown) having a predetermined gate pattern is formed on the polycrystalline silicon film 104 by photolithography, respective parts of the polycrystalline silicon film 104 and the gate insulating film formation films 102, 103 which are exposed through the opening of the mask are removed selectively by anisotropic etching. Whereby, an internal circuit gate electrode 108 is formed on the semiconductor substrate 100 in the internal circuit MIS formation region with an internal circuit gate insulating film 103A interposed while a peripheral circuit gate electrode 109 is formed on the semiconductor substrate 100 in the peripheral circuit MIS formation region with a peripheral circuit gate insulating film 102A interposed. The peripheral circuit gate insulating film 102A has a thickness larger than the internal circuit gate insulating film 103A, or the peripheral circuit gate electrode 109 has a gate length larger than the internal circuit gate electrode 108.

Thereafter, as shown in FIG. 2B, a resist film 110 that covers the internal circuit MIS formation region and is open at the peripheral circuit MIS formation region is formed on the semiconductor substrate 100 by photolithography. Then, a p-type impurity ion, such as BF₂ or the like is implanted to a region of the semiconductor substrate 100 in the peripheral circuit MIS formation region which is located below each side of the peripheral circuit gate electrode 109 with the use of the peripheral circuit gate electrode 109 and the resist film 110 as a mask to form a p-type LDD (Lightly Doped Drain) region 111, and then, the resist film 110 is removed.

Subsequently, as shown in FIG. 2C, a silicon oxide film is deposited on the entirety of the semiconductor substrate 100 by CVD and anisotropically etched to form an offset sidewall 112 made of the silicon oxide film on each side of the gate electrodes 108, 109.

Next, a resist film 113 that covers the peripheral circuit MIS formation region and is open at the internal circuit MIS formation region is formed on the semiconductor substrate 100 by photolithography. Then, a p-type impurity ion, such as boron (B) or the like is implanted to a region of the semiconductor substrate 100 in the internal circuit MIS formation region which is located below each side of the internal circuit gate electrode 108 with the use of the internal circuit gate electrode 108, the offset sidewall 112, and the resist film 113 as a mask to form a p-type extension region 114, and an n-type impurity ion, such as phosphorous (P) or the like is implanted to form an n-type pocket region 115. The resist film 113 is then removed.

Thereafter, as shown in FIG. 3A, after a silicon nitride film is deposited on the entirety of the semiconductor substrate 100 by CVD and is anisotropically etched to form a sidewall 116 on each side of the offset sidewall 112. Then, a p-type impurity ion, such as boron or the like is implanted to the semiconductor substrate 100 with the use of the gate electrodes 108, 109 and the sidewall 116 as a mask to form a p-type source/drain region 117a in a region of the semiconductor substrate 100 in the internal circuit MIS formation region which is located below each side of the sidewall 116 and a p-type source/drain region 117b in a region of the semiconductor substrate 100 in the peripheral circuit MIS formation region which is located below each side of the sidewall 116. Wherein, the p-type source/drain region 117a has a junction deeper than a junction of the p-type extension region 114 while the p-type source/drain region 117b has a junction deeper than a junction of the p-type LDD region 111.

Subsequently, as shown in FIG. 3B, a metal film 118 made of a Co film or a Ni film is deposited on the entirety of the semiconductor substrate 100 by sputtering so as to cover the sidewall 116, the offset sidewall 112, and the gate electrodes 108, 109.

Next, as shown in FIG. 3C, after a reaction of Si contained in the gate electrodes 108, 109 and the p-type source/drain regions 117a, 117b with Co or Ni contained in the metal film 118 is caused by annealing, a non-reacting part of the metal film 118 which remains on the element isolation region 101, the sidewall 116, the offset sidewall 112, and the like is removed selectively by etching. Whereby, silicide films 119 are formed which are silicided surfaces of the gate electrodes 108, 109 and the p-type source/drain regions 117a, 117b.

Thereafter, similarly to an ordinary MISFET manufacturing method, an interlayer insulating film (not shown) made of a silicon nitride film and a silicon oxide film is formed on the entirety of the semiconductor substrate 100 by, for example, CVD, and the surface thereof is planarized by chemical mechanical polishing (CMP). Then, contact holes (not sown) are formed in the interlayer insulating film so as to reach the silicide films 119 formed in the surface portions of the p-type source/drain regions 117a, 117b and the gate electrodes 108, 109. A barrier metal film (not shown) made of a TiN film and a Ti film is formed on the bottom and the side wall of each contact hole, and a tungsten (W) film is filled in each contact hole. Whereby, contact plugs (not shown) formed of the tungsten film are formed in the contact holes with the barrier metal film interposed. Then, metal wires (not shown) connecting to the contact plugs are formed on the interlayer insulating film.

Thus, a semiconductor device can be manufactured which includes the internal circuit transistor having the internal circuit fluorine introduced region 106 formed at the interface between the semiconductor substrate 100 and the internal circuit gate insulating film 103A and the peripheral circuit transistor having the peripheral circuit fluorine introduced region 107 formed at the interface between the semiconductor substrate 100 and the peripheral circuit gate insulating film 102A.

In the semiconductor device manufacturing method according to the present embodiment, the FSG film 105 that covers the surface of the polycrystalline silicon film 104 is preconditioned to contain a sufficient amount of fluorine, and fluorine is less diffused outwardly from the surface of the FSG film 105 than from a conventional fluorine-containing polysilicon film. Accordingly, the FSG film 105 functions not only as a diffusion source of fluorine but also as a cap layer, suppressing outward diffusion of fluorine.

Hence, fluorine can be diffused and introduced to the interfaces between the semiconductor substrate 100 and the gate insulating film formation films 102, 103 in the thermal treatment with no outward diffusion of the fluorine contained in the FSG film 105 caused. Whereby, as shown in FIG. 1C, the fluorine introduced regions 106, 107 can be formed at the interfaces between the semiconductor substrate 100 and the gate insulating film formation films 102, 103, respectively, preventing dangling bonds from remaining at the interfaces therebetween.

Accordingly, NBTI degradation caused due to the presence of dangling bonds at the interface between the semiconductor substrate 100 and the internal circuit gate insulating film 103A is prevented in the internal circuit transistor while NBTI degradation caused due to the presence of dangling bonds at the interface between the semiconductor substrate 100 and the peripheral circuit gate insulating film 102A is prevented in the peripheral circuit transistor. As a result, a method for manufacturing a semiconductor device including highly reliable transistors can be provided.

As described above, in Embodiment 1, the FSG film 105 functions not only as a cap layer but also a diffusion source of fluorine.

### Embodiment 2

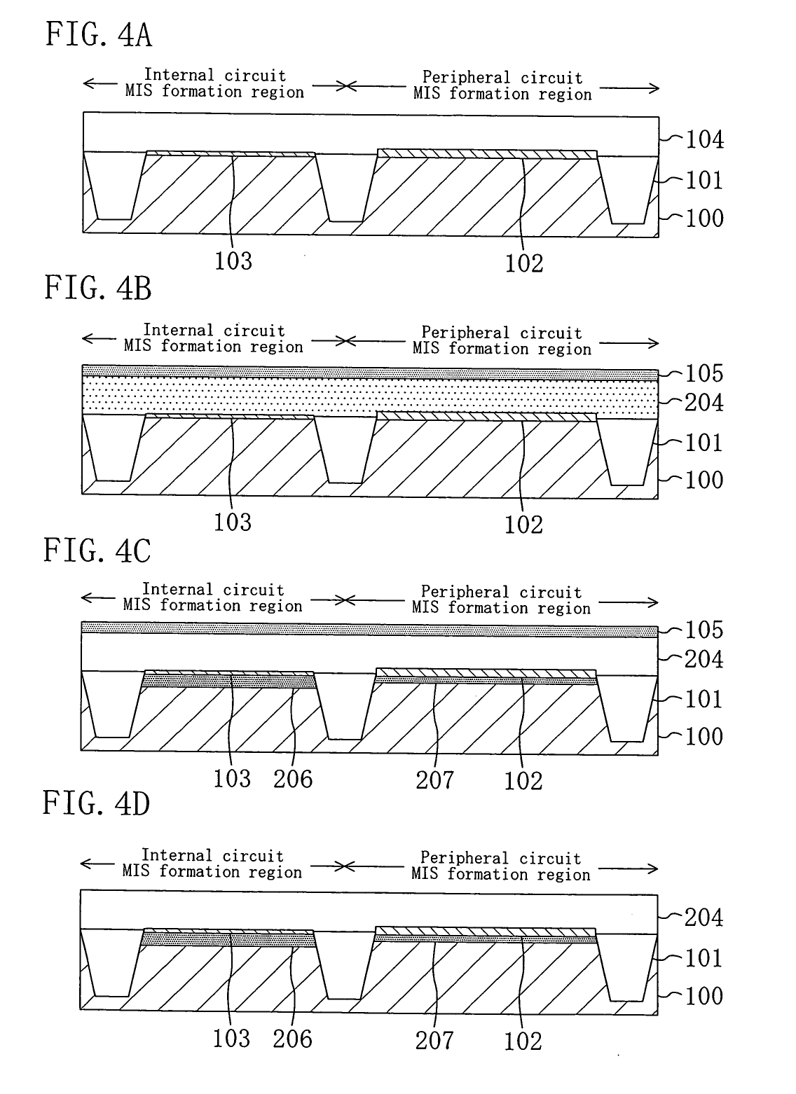

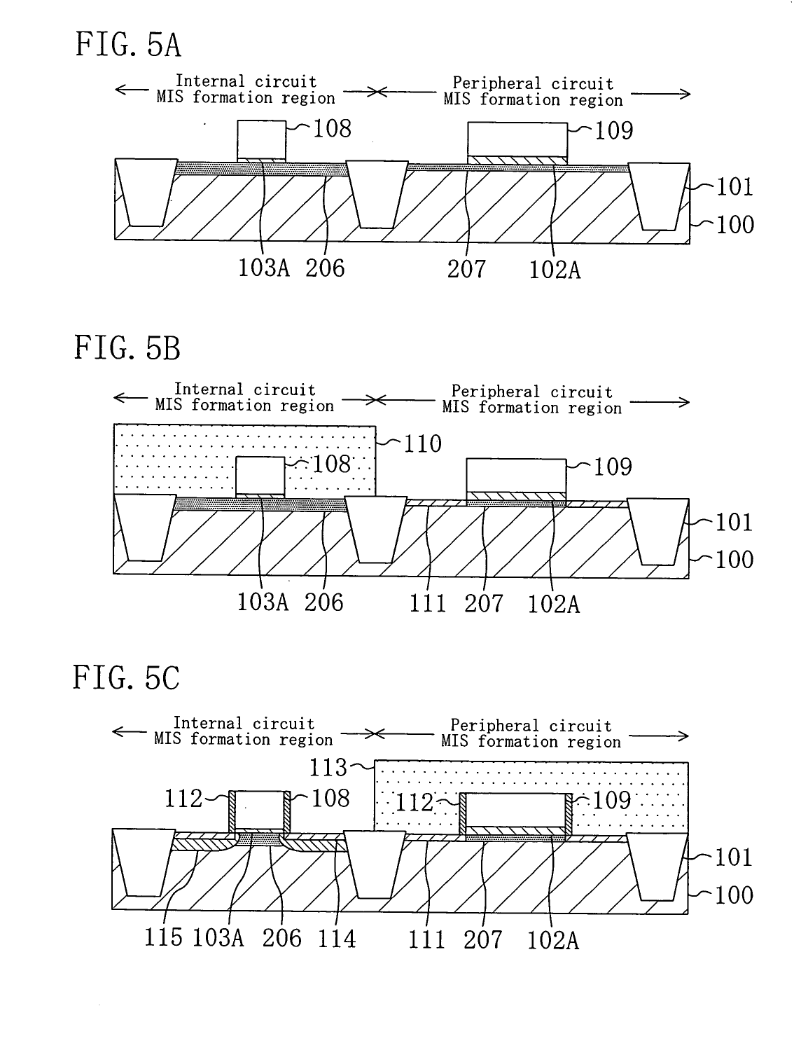

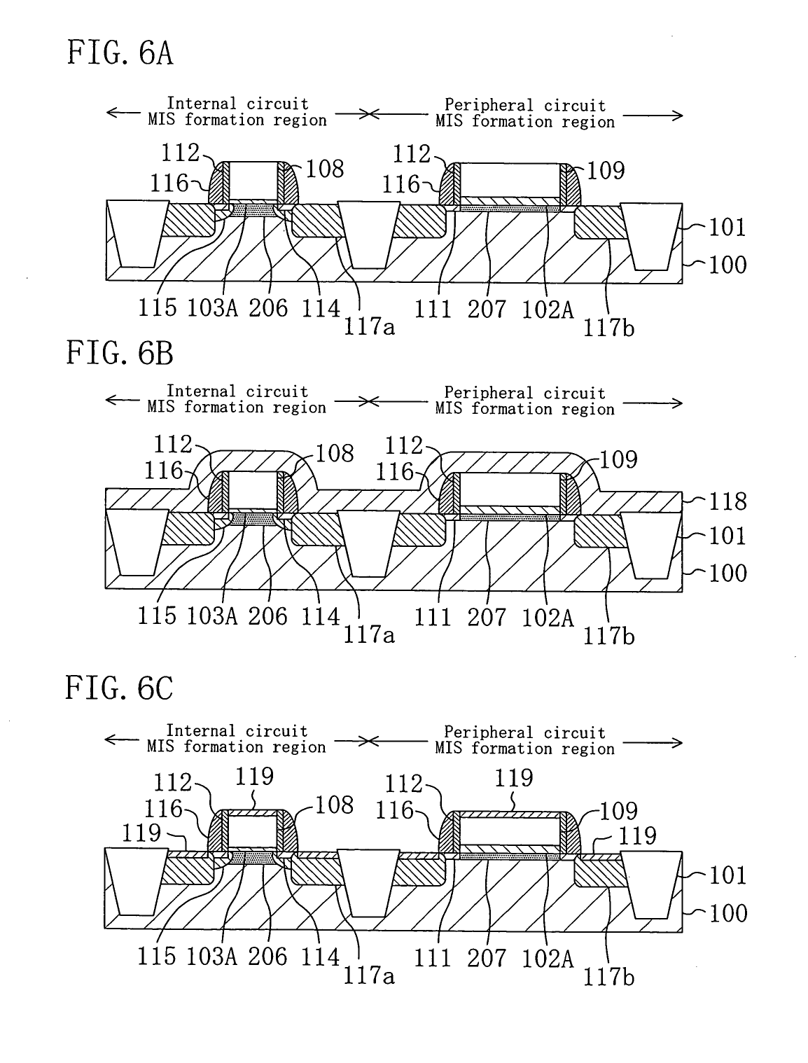

A semiconductor device manufacturing method according to Embodiment 2 of the present invention will be described by referring to a method for manufacturing a p-type MISFET with reference to FIG. 4A to FIG. 4D, FIG. 5A to FIG. 5C, and FIG. 6A to FIG. 6C. FIG. 4A to FIG. 4D, FIG. 5A to FIG. 5C, and FIG. 6A to FIG. 6C are sections showing main steps of the semiconductor device manufacturing method according to Embodiment 2 of the present invention, specifically, a method for manufacturing a semiconductor device including an internal circuit transistor and a peripheral circuit transistor. In each drawing, the left side indicates an internal circuit MIS formation region while the right side indicates a peripheral circuit MIS formation region. In FIG. 4A to FIG. 4D, FIG. 5A to FIG. 5C, and FIG. 6A to FIG. 6C, the same reference numerals are assigned to the same constitutional elements as those in the semiconductor device according to Embodiment 1 of the present invention, and description as to the same points as in Embodiment 1 is omitted.

As shown in FIG. 4A, an element isolation region 101 where a P-TEOS film is filled in a trench is formed in a semiconductor substrate 100 made of silicon. Then, thermal oxidation is performed to form a peripheral circuit gate insulating film formation film 102 having a thickness of 5 nm to 8 nm on the surface of the semiconductor substrate 100 in the peripheral circuit MIS formation region and, then, to form an internal circuit gate insulating film formation film 103 having a thickness of 2 nm on the surface of the semiconductor substrate 100 in the internal circuit MIS formation region. Then, a polycrystalline silicon film 104 is deposited on the semiconductor substrate 100 by CVD.

Subsequently, as shown in FIG. 4B, a fluorine ion is implanted to the entirety of the polycrystalline silicon film 104 to form a fluorine-containing polycrystalline silicon film 204. The fluorine-containing polycrystalline silicon film 204 herein means a polycrystalline silicon film to which fluorine is already implanted before thermal treatment in contrast to the polycrystalline silicon film 104 in Embodiment 1 which contains no fluorine before the thermal treatment.

Next, a FSG film 105 for example, as a fluorine-containing insulating film is deposited on the fluorine-containing polycrystalline silicon film 204 by CVD.

Thereafter, as shown in FIG. 4C, thermal treatment is performed to diffuse and introduce the fluorine contained in the FSG film 105 and the fluorine contained in the fluorine-containing polycrystalline silicon film 204 to the interfaces between the semiconductor substrate 100 and the gate insulating film formation films 102, 103. Whereby, an internal circuit fluorine introduced region 206 is formed at the interface between the semiconductor substrate 100 and the internal circuit gate insulating film formation film 103 while a peripheral circuit fluorine introduced region 207 is formed at the interface between the semiconductor substrate 100 and the peripheral circuit gate insulating film formation film 102. As to the thermal treatment, conditions are adjusted so that the fluorine contained in the FSG film 105 and the fluorine implanted in the fluorine-containing polycrystalline silicon film 204 are diffused to and reach the interfaces between the semiconductor substrate 100 and the gate insulating film formation films 102, 103. The fluorine-containing polycrystalline silicon film 204 after the thermal treatment serves as a fluorine-containing film containing the fluorine introduced by the ion implantation and the fluorine introduced from the FSG film 105 by the thermal treatment.

Subsequently, as shown in FIG. 4D, wet etching is performed to remove only the FSG film 105 selectively.

Next, as shown in FIG. 5A, photolithography and anisotropic etching are performed to form an internal circuit gate electrode 108 on the semiconductor substrate 100 in the internal circuit MIS formation region with an internal circuit gate insulating film 103A interposed and a peripheral circuit gate electrode 109 on the semiconductor substrate 100 in the peripheral circuit MIS formation region with a peripheral circuit gate insulating film 102A interposed. The peripheral circuit gate insulating film 102A has a thickness larger than the internal circuit gate insulating film 103A, or the peripheral circuit gate electrode 109 has a gate length larger than the internal circuit gate electrode 108.

Thereafter, as shown in FIG. 5B, photolithography is performed to form on the semiconductor substrate 100 a resist film 110 that covers the internal circuit MIS formation region and is open at the peripheral circuit MIS formation region. Then, a p-type impurity ion, such as BF₂ or the like is implanted to a region of the semiconductor substrate 100 in the peripheral circuit MIS formation region which is located below each side of the peripheral circuit gate electrode 109 with the use of the peripheral circuit gate electrode 109 and the resist film 110 as a mask to form a p-type LDD region 111. The resist film 110 is then removed.

Subsequently, as shown in FIG. 5C, after a silicon oxide film is deposited on the entirety of the semiconductor substrate 100 by CVD, anisotropic etching is performed on the thus formed silicon oxide film to form an offset sidewall 112 made of the silicon oxide film on each side of the gate electrodes 108, 109.

Next, photolithography is performed to form on the semiconductor substrate 100 a resist film 113 that covers the peripheral circuit MIS formation region and is open at the internal circuit MIS formation region. Then, a p-type impurity ion, such as boron (B) or the like is implanted to a region of the semiconductor substrate 100 in the internal circuit MIS formation region which is located below each side of the internal circuit gate electrode 108 with the use of the internal circuit gate electrode 108, the offset sidewall 112, and the resist film 113 as a mask to form a p-type extension region 114. Then, a n-type impurity ion, such as phosphorous (P) or the like is implanted to form a n-type pocket region 115, and the resist film 113 is removed.

Thereafter, as shown in FIG. 6A, a silicon nitride film is deposited on the entirety of the semiconductor substrate 100 by CVD and is etched back to form a sidewall 116 on each side of the offset sidewall 112. Then, a p-type impurity ion, such as B is implanted to a region of the semiconductor substrate 100 which is located below each side of the sidewall 116 to form p-type source/drain regions 117a, 117b.

Subsequently, as shown in FIG. 6B, a metal film 118 made of a Co film or a Ni film is deposited on the entirety of the semiconductor substrate 100 by sputtering so as to cover the sidewall 116, the offset sidewall 112, and the gate electrodes 108, 109.

Next, as shown in FIG. 6C, annealing is performed to cause a reaction of Si contained in the gate electrodes 108, 109 and the p-type source/drain regions 117a, 117b with Co or Ni contained in the metal film 118, and then, etching is performed to remove selectively a non-reacting part of the metal film 118 which remains on the semiconductor substrate 100. Whereby, silicide films 119 are formed which are silicided surfaces of the gate electrodes 108, 109 and the p-type source/drain regions 117a, 117b.

Thereafter, similarly to an ordinary MISFET manufacturing method, an interlayer insulating film (not shown) made of a silicon nitride film and a silicon oxide film is formed on the entirety of the semiconductor substrate 100 by, for example, CVD, and the surface thereof is planarized by CMP. Then, contact holes (not sown) are formed in the interlayer insulating film so as to reach the silicide films 119 formed in the surface portions of the p-type source/drain regions 117a, 117b and the gate electrodes 108, 109. A barrier metal film (not shown) made of a TiN film and a Ti film is formed on the bottom and the side wall of each contact hole, and a tungsten (W) film is filled in each contact hole. Whereby, contact plugs (not shown) formed of the tungsten film are formed in the contact holes with the barrier metal film interposed. Then, metal wires (not shown) connecting to the contact plugs are formed on the interlayer insulating film.

Thus, a semiconductor device can be manufactured which includes the internal circuit transistor having the internal circuit fluorine introduced region 206 formed at the interface between the semiconductor substrate 100 and the internal circuit gate insulating film 103A and the peripheral circuit transistor having the peripheral circuit fluorine introduced region 207 formed at the interface between the semiconductor substrate 100 and the peripheral circuit gate insulating film 102A.

In the semiconductor device manufacturing method according to the present embodiment, the FSG film 105 that covers the surface of the fluorine-containing polycrystalline silicon film 204 is preconditioned to contain a sufficient amount of fluorine. Accordingly, there is no path for fluorine to enter into the FSG film 105 from the fluorine-containing polysilicon crystalline film 204 in the thermal treatment, which means that the FSG film 105 functions as a cap layer, surely preventing outward diffusion of fluorine.

Accordingly, both the fluorine contained in the FSG film 105 and the fluorine implanted in the fluorine-containing polycrystalline silicon film 204 can be diffused and introduced to the interfaces between the semiconductor substrate 100 and the gate insulating film formation films 102, 103 in the thermal treatment with no outward diffusion of the fluorines caused, increasing the fluorine concentration of the fluorine introduced regions 206, 207 when compared with Embodiment 1.

In view of that, a sufficient amount of fluorine, that is, fluorine of which amount corresponds to the amount of dangling bonds can be diffused and introduced surely to the interfaces between the semiconductor substrate 100 and the gate insulating film formation films 102, 103, preventing the dangling bonds from remaining at the interfaces therebetween.

Hence, NBTI degradation caused due to the presence of dangling bonds at the interface between the semiconductor substrate 100 and the internal circuit gate insulating film 103A is prevented in the internal circuit transistor while NBTI degradation caused due to the presence of dangling bonds at the interface between the semiconductor substrate 100 and the peripheral circuit gate insulating film 102A is prevented in the peripheral circuit transistor. As a result, a method for manufacturing a semiconductor device including highly reliable transistors can be provided.

As described above, the FSG film 105 in the present embodiment functions as a cap layer predominantly while functioning as a diffusion source of fluorine as well as in Embodiment 1. Specifically, the FSG film 105 functions to prevent outward diffusion of the fluorine contained in the fluorine-containing polycrystalline silicon film 204 in the thermal treatment reliably. In contrast, in Embodiment 1, the FSG film 105 functions as a cap layer and a diffusion source of fluorine evenly.

### Embodiment 3

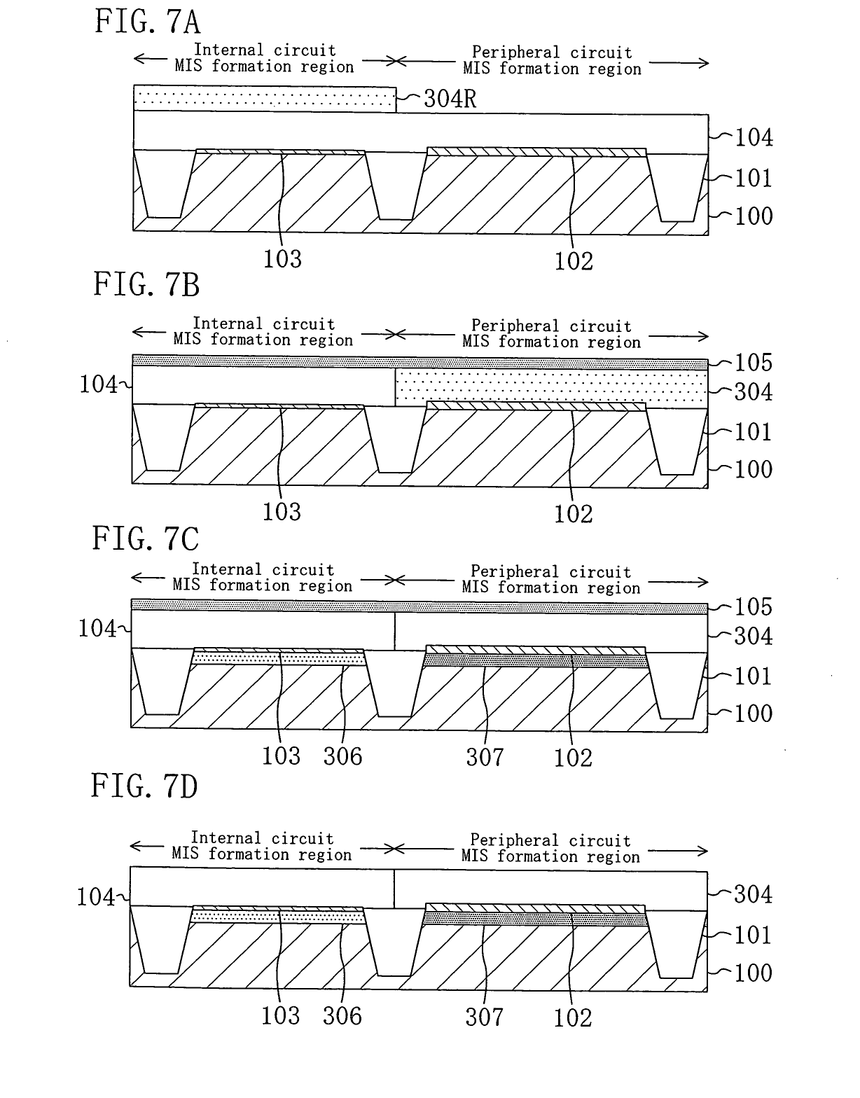

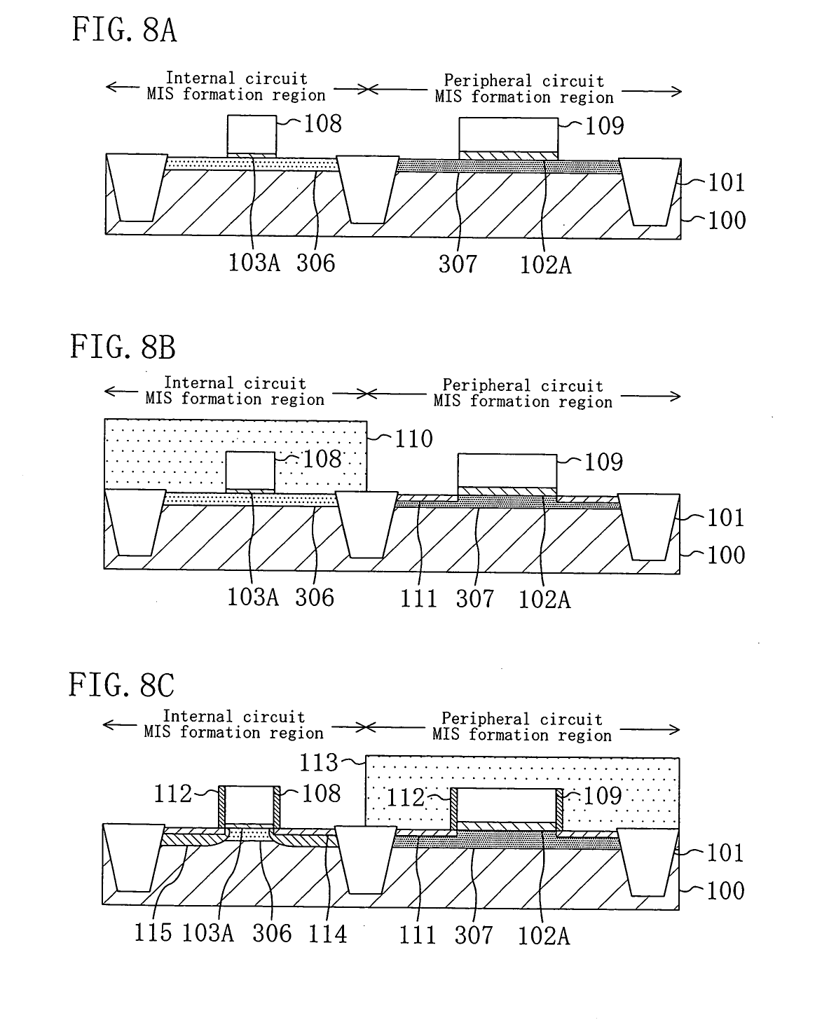

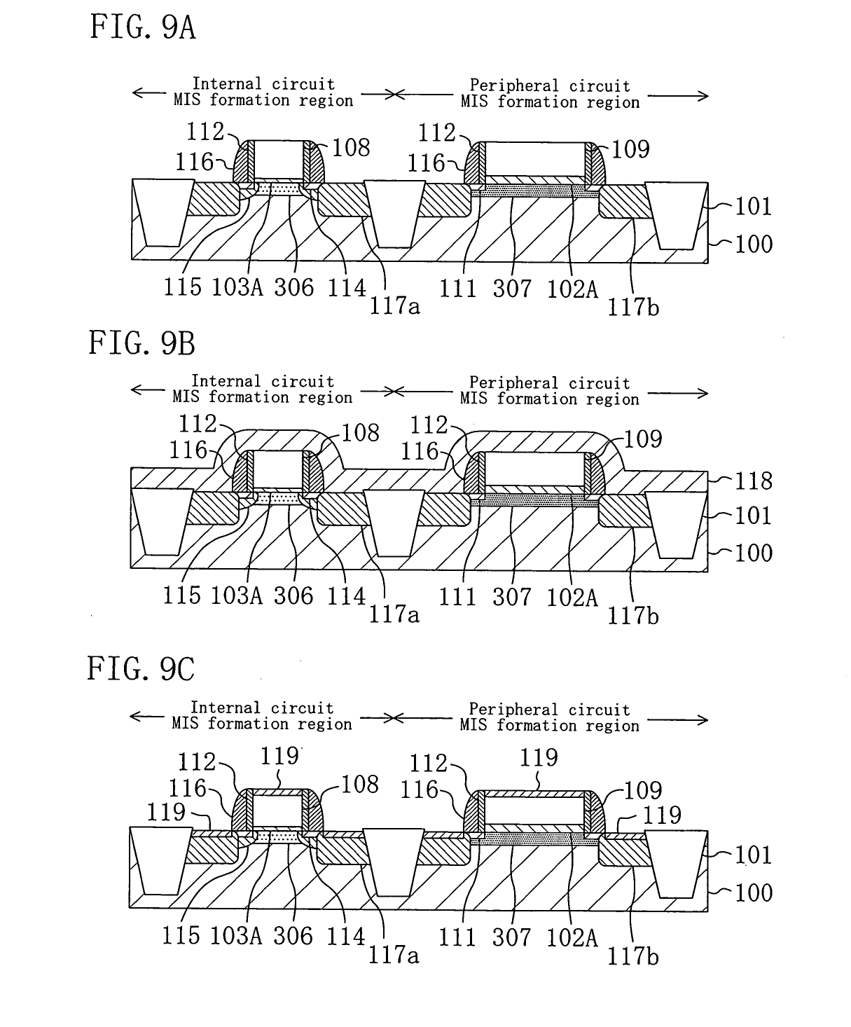

A semiconductor device manufacturing method according to Embodiment 3 of the present invention will be described by referring to a method for manufacturing a p-type MISFET with reference to FIG. 7A to FIG. 7D, FIG. 8A to FIG. 8C, and FIG. 9A to FIG. 9C. FIG. 7A to FIG. 7D, FIG. 8A to FIG. 8C, and FIG. 9A to FIG. 9C are sections showing main steps of the semiconductor device manufacturing method according to Embodiment 3 of the present invention, specifically, a method for manufacturing a semiconductor device including an internal circuit transistor and a peripheral circuit transistor. In each drawing, the left side indicates an internal circuit MIS formation region while the right side indicates a peripheral circuit MIS formation region. In FIG. 7A to FIG. 7D, FIG. 8A to FIG. 8C, and FIG. 9A to FIG. 9C, the same reference numerals are assigned to the same constitutional elements as those in the semiconductor device according to Embodiment 1 of the present invention, and description as to the same points as that in Embodiment 1 is omitted.

As shown in FIG. 7A, an element isolation region 101 where a P-TEOS film is filled in a trench is formed in a semiconductor substrate 100 made of silicon. Then, thermal oxidation is performed to form a peripheral circuit gate insulating film formation film 102 having a thickness of 5 nm to 8 nm on the surface of the semiconductor substrate 100 in the peripheral circuit MIS formation region and, then, to form an internal circuit gate insulating film formation film 103 having a thickness of 2 nm on the surface of the semiconductor substrate 100 in the internal circuit MIS formation region. Then, after a polycrystalline silicon film 104 is deposited on the semiconductor substrate 100 by CVD, a resist film 304R that covers the internal circuit MIS formation region and is open at the peripheral circuit MIS formation region is formed on the polycrystalline silicon film 104. A fluorine ion is selectively implanted to a part of the polycrystalline silicon film 104 which is exposed through the opening of the resist film 304R, that is, the polycrystalline silicon film 104 in the peripheral circuit MIS formation region to form a fluorine-containing polycrystalline silicon film 304 selectively.

Subsequently, as shown in FIG. 7B, after the resist film 304R is removed, a FSG film 105, for example, as a fluorine-containing insulating film is deposited on the polycrystalline silicon film 104 and the fluorine-containing polycrystalline silicon film 304 by CVD.

Next, as shown in FIG. 7C, thermal treatment is performed to diffuse and introduce the fluorine contained in the FSG film 105 to the interfaces between the semiconductor substrate 100 and the gate insulating film formation films 102, 103 and to diffuse and introduce the fluorine implanted in the fluorine-containing polycrystalline silicon film 304 only to the interface between the semiconductor substrate 100 and the peripheral circuit gate insulating film formation film 102. Whereby, an internal circuit fluorine introduced region 306 is formed at the interface between the semiconductor substrate 100 and the internal circuit gate insulating film formation film 103 while a peripheral circuit fluorine introduced region 307 is formed at the interface between the semiconductor substrate 100 and the peripheral circuit gate insulating film formation film 102.

Thereafter, as shown in FIG. 7D, wet etching is performed to remove the FSG film 105 selectively.

Subsequently, as shown in FIG. 8A, photolithography and anisotropic etching are performed to form an internal circuit gate electrode 108 on the semiconductor substrate 100 in the internal circuit MIS formation region with an internal circuit gate insulting film 103A interposed and a peripheral circuit gate electrode 109 on the semiconductor substrate 100 in the peripheral circuit MIS formation region with a peripheral circuit gate insulating film 102A interposed. The peripheral circuit gate insulating film 102A has a thickness larger than the internal circuit gate insulting film 103A, or the peripheral circuit gate electrode 109 has a gate length larger than the internal circuit gate electrode 108.

Next, as shown in FIG. 8B, photolithography is performed to form on the semiconductor substrate 100 a resist film 110 that covers the internal circuit MIS formation region and is open at the peripheral circuit MIS formation region. Then, a p-type impurity ion, such as BF₂ or the like is implanted to a region of the semiconductor substrate 100 in the peripheral circuit MIS formation region which is located below each side of the peripheral circuit gate electrode 109 with the use of the peripheral circuit gate electrode 109 and the resist film 110 as a mask to form a p-type LDD region 111. The resist film 110 is then removed.

Thereafter, as shown in FIG. 8C, after a silicon oxide film is deposited on the entirety of the semiconductor substrate 100 by CVD and is anisotropically etched to form an offset sidewall 112 made of the silicon oxide film on each side of the gate electrodes 108, 109.

Subsequently, photolithography is performed to form on the semiconductor substrate 100 a resist film 113 that covers the peripheral circuit MIS formation region and is open at the internal circuit MIS formation region. Then, a p-type impurity ion, such as boron (B) or the like is implanted to a region of the semiconductor substrate 100 in the internal circuit MIS formation region which is located below each side of the internal circuit gate electrode 108 with the use of the internal circuit gate electrode 108, the offset sidewall 112, and the resist film 113 as a mask to form a p-type extension region 114. Then, a n-type impurity ion, such as phosphorous (P) or the like is implanted to form a n-type pocket region 115. The resist film 113 is then removed.

Next, as shown in FIG. 9A, a silicon nitride film is deposited on the entirety of the semiconductor substrate 100 by CVD and is etched back to form a sidewall 116 on each side of the offset sidewall 112. Then, a p-type impurity ion, such as B or the like is implanted to a region of the semiconductor substrate 100 which is located below each side of the sidewall 116 to form p-type source/drain regions 117a, 117b.

Thereafter, as shown in FIG. 9B, a metal film 118 made of a Co film or a Ni film is deposited on the entirety of the semiconductor substrate 100 by sputtering so as to cover the sidewall 116, the offset sidewall 112, and the gate electrodes 108, 109.

Subsequently, as shown in FIG. 9C, after annealing is performed to cause a reaction of Si contained in the gate electrodes 108, 109 and the p-type source/drain regions 117a, 117b with Co or Ni contained in the metal film 118, etching is performed to remove a non-reacting part of the metal film 118 which remains on the semiconductor substrate 100. Whereby, silicide films 119 are formed which are silicided surfaces of the gate electrodes 108, 109 and the p-type source/drain regions 117a, 117b.

Next, similarly to an ordinary MISFET manufacturing method, an interlayer insulating film (not shown) made of a silicon nitride film and a silicon oxide film is formed on the entirety of the semiconductor substrate 100 by, for example, CVD, and the surface thereof is planarized by CMP. Then, contact holes (not sown) are formed in the interlayer insulating film so as to reach the silicide films 119 formed in the surface portions of the p-type source/drain regions 117a, 117b and the gate electrodes 108, 109. A barrier metal film (not shown) made of a TiN film and a Ti film is formed on the bottom and the side wall of each contact hole, and a tungsten (W) film is filled in each contact hole. Whereby, contact plugs (not shown) formed of the tungsten film are formed in the contact holes with the barrier metal film interposed. Then, metal wires (not shown) connecting to the contact plugs are formed on the interlayer insulating film.

Thus, a semiconductor device can be manufactured which includes the internal circuit transistor having the internal circuit fluorine introduced region 306 formed at the interface between the semiconductor substrate 100 and the internal circuit gate insulating film 103A and the peripheral circuit transistor having the peripheral circuit fluorine introduced region 307 formed at the interface between the semiconductor substrate 100 and the peripheral circuit gate insulating film 102A.

In the semiconductor device manufacturing method according to the present embodiment, as shown in FIG. 7C, the FSG film 105 that covers the surfaces of the polycrystalline silicon film 104 and the fluorine-containing polycrystalline silicon film 304 is preconditioned to contain a sufficient amount of fluorine. Accordingly, there is no path for the fluorine from the fluorine-containing polycrystalline silicon film 304 to enter into the FSG film 105 in the thermal treatment, which means that the FSG film 105 functions as a cap layer. Thus, outward diffusion of fluorine is prevented surely.

Hence, in the thermal treatment, the fluorine contained in the FSG film 105 can be diffused and introduced to the interfaces between the semiconductor substrate 100 and the gate insulating film formation films 102, 103 with no outward diffusion thereof caused while the fluorine implanted in the fluorine-containing polycrystalline silicon film 304 can be diffused and introduced selectively to the interface between the semiconductor substrate 100 and the peripheral circuit gate insulating film formation film 102 with no outward diffusion thereof caused. In turn, the internal circuit fluorine introduced region 306 is formed at the interface between the semiconductor substrate 100 and the internal circuit gate insulating film formation film 103 while the peripheral circuit fluorine introduced region 307 having a fluorine concentration higher than the internal circuit fluorine introduced region 306 is formed at the interface between the semiconductor substrate 100 and the peripheral circuit gate insulating film formation film 102.

In the semiconductor device manufacturing method according to the present embodiment, as shown in FIG. 7A, fluorine is selectively implanted to the polycrystalline silicon film 104 in the peripheral circuit MIS formation region with the use of the resist film 304R that covers the polycrystalline silicon film 104 in the internal circuit MIS formation region to form the fluorine-containing polycrystalline silicon film 304 selectively.

Accordingly, in the thermal treatment, both the fluorine contained in the FSG film 105 and the fluorine implanted in the fluorine-contained polycrystalline silicon film 304 can be diffused and introduced to the interface between the semiconductor substrate 100 and the peripheral circuit gate insulating film formation film 102 which is to compose a peripheral circuit transistor at which NBTI degradation might be caused significantly, and only the fluorine contained in the FSG film 105 is diffused and introduced only to the interface between the semiconductor substrate 100 and the internal circuit gate insulating film formation film 103 which is to compose an internal circuit transistor at which NBTI degradation might be less caused.

As described above, selective implantation of fluorine to a part of the polycrystalline silicon film 104 according to a degree of NBTI degradation to be caused in each transistor leads to selective diffusion and introduction of the fluorine implanted in the fluorine-containing polycrystalline silicon film 304 in the thermal treatment only to the interface between the semiconductor substrate 100 and the peripheral circuit gate insulating film formation film 102 which is to compose the peripheral circuit transistor at which NBTI degradation might be caused significantly. Hence, NBTI degradation is effectively prevented in the peripheral circuit transistor.

Further, only the fluorine contained in the FSG film 105 can be diffused and introduced selectively to the interface between the semiconductor substrate 100 and the internal circuit gate insulating film formation film 103 which is to compose the internal circuit transistor, so that surplus fluorine, that is, fluorine in excess of dangling bonds can be prevented effectively from being introduced, and NBTI degradation can be prevented in the internal circuit transistor.

In the above embodiments, the p-type MISFET manufacturing methods are described as semiconductor device manufacturing methods, but the present invention is not limited thereto and can be applicable to n-type MISFET manufacturing methods as well.

Further, semiconductor devices each including both the internal circuit transistor and the peripheral circuit transistor are described in the above embodiments, but the present invention is not limited thereto. The same effects as in the present invention can be obtained in, for example, a semiconductor device including only an internal circuit transistor and in a semiconductor device including only a peripheral circuit transistor.

Embodiment 3 describes the case where fluorine is selectively implanted to the polycrystalline silicon film 104 in the peripheral circuit MIS formation region, but the present invention is not limited thereto. The same effects as in Embodiment 3 can be obtained in the case where fluorine is implanted selectively to the polycrystalline silicon film in any MIS formation region where NBTI degradation might be caused significantly.

For example, the more thinning of gate insulting films progresses, the more an amount of nitrogen to be introduced in the gate insulating films increases for the purpose of ensuring the dielectric constants of the gate insulating films. The nitrogen introduced in the gate insulating films becomes fixed charges. Therefore, the fixed charges present at the interface between a semiconductor substrate and a gate insulating film increases in association with the increase in the amount of nitrogen introduced in the gate insulating film, accelerating NBTI degradation. In this case, NBTI degradation may be caused significantly in the internal circuit transistor and may be more significant than in the peripheral circuit transistor. In view of this, when fluorine is implanted selectively to the polycrystalline silicon film in the internal circuit MIS formation region, NBTI degradation can be prevented effectively, similarly to in Embodiment 3.

As described above, the present invention attains reliable prevention of outward diffusion of fluorine in the step of introducing fluorine to the interface between the semiconductor substrate and the gate insulating film formation films by the thermal treatment, preventing NBTI degradation caused due to the presence of dangling bonds at the interface between the semiconductor substrate and the gate insulating films. Hence, the present invention is useful in semiconductor device manufacturing methods.

What is claimed is:

1. A semiconductor device manufacturing method, comprising the steps of:
(a) forming a gate insulating film formation film in an element formation region on a semiconductor substrate;
(b) forming a gate electrode formation film on the gate insulating film formation film;
(c) forming a fluorine-containing insulting film on the gate electrode formation film; and
(d) diffusing and introducing, by thermal treatment, fluorine contained in the fluorine-containing insulating film to an interface between the semiconductor substrate and the gate insulting film formation film.

2. The semiconductor device manufacturing method of claim 1, further comprising the step of:
(x) implanting fluorine to the gate electrode formation film after the step (b) and before the step (c),
wherein the step (d) includes a step of diffusing and introducing the fluorine implanted in the gate electrode formation film to the interface between the semiconductor substrate and the gate insulating film formation film.

3. The semiconductor device manufacturing method of claim 1, further comprising the steps of:
(e) removing the fluorine-containing insulating film after the step (d);
(f) forming a gate insulting film and a gate electrode by patterning the gate insulating film formation film and the gate electrode formation film; and
(g) forming an extension region in a region of the semiconductor substrate which is located below each side of the gate electrode after the step (f).

4. The semiconductor device manufacturing method of claim 3, further comprising the step of:
(h) forming a sidewall on each side of the gate electrode after the step (g); and
(i) forming a source/drain region in a region of the semiconductor substrate which is located below each side of the sidewall after the step (h).

5. The semiconductor device manufacturing method of claim 2, further comprising the steps of:
(e) removing the fluorine-containing insulating film after the step (d);
(f) forming a gate insulting film and a gate electrode by patterning the gate insulating film formation film and the gate electrode formation film; and
(g) forming an extension region in a region of the semiconductor substrate which is located below each side of the gate electrode after the step (f).

6. The semiconductor device manufacturing method of claim 5, further comprising the step of:
(h) forming a sidewall on each side of the gate electrode after the step (g); and
(i) forming a source/drain region in a region of the semiconductor substrate which is located below each side of the sidewall after the step (h).

7. The semiconductor device manufacturing method of claim 1,
wherein the step (a) includes a step of forming a first gate insulating film formation film as a part of the gate insulating film formation film in a first region in the element formation region and forming a second gate insulating film formation film as the other part of the gate insulting film formation film in a second region other than the first region in the element formation region, and
the step (b) includes a step of forming a first gate electrode formation film as a part of the gate electrode formation film on the first gate insulating formation film and forming a second gate electrode formation film as the other part of the gate electrode formation film on the second gate insulating film formation film.

8. The semiconductor device manufacturing method of claim 7, further comprising the step of:
(x) implanting fluorine to one of the first gate electrode formation film and the second gate electrode formation film after the step (b) and before the step (c),
wherein the step (d) includes a step of diffusing and introducing the fluorine implanted in the step (x) to an interface between the semiconductor substrate and the first gate insulating film formation film or the second gate insulating film formation film which is located below the one of the gate electrode formation films.

9. The semiconductor device manufacturing method of claim 7, further comprising the steps of:
(e) removing the fluorine-containing insulating film after the step (d);
(f) forming a first gate insulating film and a first gate electrode by patterning the first gate insulating film formation film and the first gate electrode formation film and a second gate insulating film and a second gate electrode by patterning the second gate insulating film formation film and the second gate electrode formation film; and
(g) forming an extension region in a region of the semiconductor substrate which is located below each side of the first gate electrode and forming a LDD region in a region of the semiconductor substrate which is located below each side of the second gate electrode after the step (f).

10. The semiconductor device manufacturing method of claim 9, further comprising the steps of:
(h) forming a first sidewall on each side of the first gate electrode and a second sidewall on each side of the second gate electrode after the step (g); and
(i) forming a first source/drain region in a region of the semiconductor substrate which is located below each side of the first sidewall and a second source/drain region in a region of the semiconductor substrate which is located below each side of the second sidewall after the step (h).

11. The semiconductor device manufacturing method of claim 8, further comprising the steps of:
(e) removing the fluorine-containing insulating film after the step (d);
(f) forming a first gate insulating film and a first gate electrode by patterning the first gate insulating film formation film and the first gate electrode formation film and a second gate insulating film and a second gate electrode by patterning the second gate insulating film formation film and the second gate electrode formation film; and
(g) forming an extension region in a region of the semiconductor substrate which is located below each side of the first gate electrode and forming a LDD region in a region of the semiconductor substrate which is located below each side of the second gate electrode after the step (f).

12. The semiconductor device manufacturing method of claim 11, further comprising the steps of:
(h) forming a first sidewall on each side of the first gate electrode and a second sidewall on each side of the second gate electrode after the step (g); and
(i) forming a first source/drain region in a region of the semiconductor substrate which is located below each side of the first sidewall and a second source/drain region in a region of the semiconductor substrate which is located below each side of the second sidewall after the step (h).
